(19) United States
(12) Patent Application Publication
(10) Pub. No.: US 2013/0081695 A1
(43) Pub. Date: Apr. 4, 2013

(54) THIN SHEET FOR SOLAR CELL MODULE

(71) Applicants: Tsun-Min HSU, Kaohsiung (TW); Chi-Tsung HUANG, Kaohsiung (TW); Hao-Tien BAI, Kaohsiung (TW)

(72) Inventors: Tsun-Min HSU, Kaohsiung (TW); Chi-Tsung HUANG, Kaohsiung (TW); Hao-Tien BAI, Kaohsiung (TW)

(73) Assignee: ETERNAL CHEMICAL CO., LTD..

(21) Appl. No.: 13/598,669

(22) Filed: Aug. 30, 2012

(30) Foreign Application Priority Data
Sep. 30, 2011 (TW) 100135796

(51) Int. Cl. C09D 127/12; H01L 31/0203; C09D 133/00; C09D 127/16; C09D 127/18; C09D 127/20; B32B 27/08; C09D 127/04

(52) U.S. Cl. 136/259; 428/412; 428/422; 524/544; 524/545; 524/520

(57) ABSTRACT

A thin sheet for a solar cell module is provided, which includes a substrate and at least one fluoro-containing coating layer, wherein the fluoro-containing coating layer includes: (a) a fluoro resin, including a homopolymer or a copolymer formed with a fluoro olefin monomer selected from the group consisting of monofluoroethylene, vinylidene fluoride, chlorotrifluoroethylene, tetrafluoroethylene, hexafluoropropylene, and a combination thereof; (b) an adhesion promoter of the formula R¹Si(R²)₃; and (c) an adhesion co-promoter, wherein R¹ and R² are as defined in the specification. A solar cell module having the thin sheet is further provided.

### BACKGROUND OF THE INVENTION

1. Field of the Invention

The present invention relates to a thin sheet for a solar cell module and a solar cell module having the thin sheet.

2. Description of the Related Art

Due to the increasingly serious environmental problems such as energy shortage and greenhouse effect, all countries are actively involved in development of various potential alternative energy sources at present, and among which, solar power has attracted great interests in all industries.

As shown in FIG. 1, a solar cell module is generally formed by a transparent front sheet 11 (which is generally a glass sheet), a solar cell unit 13 contained in an encapsulation material layer 12, and a back sheet 14.

The back sheet 14 functions to protect the solar cell module against environmental damages, and provides electrical insulation properties and aesthetic effects. In order to avoid deterioration of the solar cell module due to contact with moisture, oxygen, or UV light in the environment, the back sheet needs to have good moisture and air barrier properties and good UV resistance. Furthermore, the back sheet 14 is required to be effectively and firmly adhered to the encapsulation material layer 12 for a long period of time, and thus required to have a good adhesion to an encapsulation material (for example, ethylene vinyl acetate (EVA) copolymer) of the encapsulation material layer 12.

The commonly used back sheet material in this field has been a metal substrate or a glass material. Recently, a plastic substrate (for example, a polyester substrate) has gradually replaced metal substrate due to the advantages of being tight weight and relatively low manufacturing cost. However, plastic substrate is susceptible to environmental influence and can be easily degraded, so a fluoro-containing polymer having good moisture and air barrier properties and good anti-UV properties, as well as particularly excellent mechanical strength and electrical insulation properties, is employed as a protection layer of the plastic substrate in this field. At present, as a commercially available plastic substrate back sheet having a fluoro-containing polymer protection layer, a laminated film composite sheet having a tri-layer structure of Tedlar®/polyester/Tedlar® is very popular, which has excellent mechanical strength, light stability, chemical resistance, and weather resistance. However, in the fabrication of the multi-layer back sheet, a fluoro-containing polymer needs to be first fabricated into a film, and then laminated to a plastic substrate. Therefore, additional process apparatuses are required, and the problem of high manufacturing cost occurs.

U.S. Pat. No. 7,553,540 discloses that a fluoro-containing polymer coating is prepared by blending a homopolymer or a copolymer of fluoroethylene and vinylidene fluoride and an adhesive polymer having a functional group such as 3 carboxyl or sulfo group, and a function group capable of reacting with the adhesive polymer is introduced into a plastic substrate, to improve the adhesion force between the fluoro-containing polymer and the substrate. While this method is feasible to apply a fluoro-containing polymer coating onto a plastic substrate, in place of the conventionally known technology of laminating the fluoro-containing polymer film and the substrate, the method is only applicable to a specific substrate, or alternatively the substrate needs to be subjected to surface treatment first, no that the surface of the substrate has the desired functional groups.

In addition, the adhesion force is generally poor when the back sheet having the fluoro-containing polymer is attached to encapsulation material (for example, EVA), due to the poor wettability of the fluoro-containing polymer. Therefore, before attachment, the back sheet needs to be subjected to surface treatment or an adhesive layer needs to be additionally applied on the surface of the back sheet. For example, TW 201034850 discloses that a coating layer formed with one or more acrylic polymers or one or more fluoropolymers is used as the back sheet material, in which a primer is used, so that the back sheet is firmly adhered to the EVA layer. TW 201007961 discloses a tertiary copolymer coating layer containing chlorotrifluoroethylene (CTFE), to which an adhesive layer may be further added to improve the adhesion with the EVA layer. Because the need to use the primer or the additional adhesive layer exists in prior art, the problems of troublesome process and high process cost still exist.

### SUMMARY OF THE INVENTION

Given the above, the inventors of the present invention finds, after extensive research and repeated experimentation, a novel thin sheet for a solar cell module, whereby the problems above-described can be effectively solved. The thin sheet of the present invention has a special fluoro-containing coating layer, which has an excellent adhesion strength with EVA, and thus can be directly attached to EVA, while the foregoing treatment or process of using an additional adhesive layer is omitted, so as to simplify the procedural steps and to lower the cost. In addition, the thin sheet of the present invention has good adhesion with the EVA encapsulation material layer; therefore, the release of the back sheet from the solar cell due to exposure to the environment for a long period of time can be avoided, and the service life of the solar cell module can be extended.

A main objective of the present invention is to provide a thin sheet for a solar cell module, which can be directly thermal-laminated to an EVA layer and have, an excellent adhesion strength.

In order to achieve the above objective, the present invention provides a thin sheet for a solar cell module, which includes a substrate and at least one fluoro-containing coating layer, wherein the fluoro-containing coating layer includes:

(a) a fluoro resin, comprising a homopolymer or a copolymer formed from a fluoro olefin monomer selected from the group consisting of monofluoroethylene, vinylidene fluoride, chlorotrifluoroethylene, to tetrafluoroethylene, hexafluoropropylene, and a combination thereof; and

(b) an adhesion promoter of the formula:

R¹Si(R²)₃,

wherein R¹ is an organic group having a terminal amino, isocyanate group, epoxy group, vinyl or (meth)acryloxy, R² is each independently selected from the group consisting of a linear or branched C₁₋₄ alkyl, a linear or branched C₁₋₄ alkoxy, and hydroxyl; and

(c) an adhesion co-promoter.

The present invention has the following beneficial effects. The thin sheet of the present invention has a special fluoro-containing coating layer and can be fabricated by using an existing coating apparatus, to solve the problem of multi-layer attachment required in the prior art. The fluoro-containing coating layer of the present invention has a fluoro resin, an adhesion promoter, and an adhesion co-promoter, and the coating layer has an excellent adhesion strength with EVA and thus can be directly attached to EVA, eliminating the above-mentioned treatment or the use of an additional adhesive layer, so as to simplify the process steps and lower the cost; and meanwhile, the fluoro-containing coating layer of the present invention has the advantages of good adhesion to the substrate, good adhesion to EVA, and is capable of extending the service life of the solar cell module.

### BRIEF DESCRIPTION OF THE DRAWINGS

FIG. 1 is a schematic view of a solar cell module.

FIG. 2 is as schematic view of a peeling strength test method.

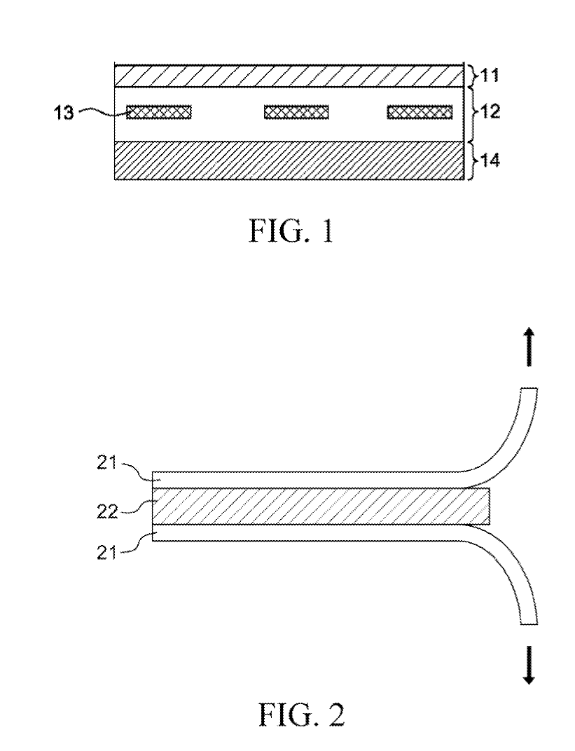

### DETAILED DESCRIPTION OF THE INVENTION

The substrate suitable for use in the present invention may be any substrate known to persons of ordinary skill in the art, and preferably a plastic substrate. The plastic substrate is not particularly limited, and is well known to persons of ordinary skill in the art, which includes, for example, but is not limited to, a polyester resin such as polyethylene terephthalate (PET) or polyethylene naphthalate (PEN); a polyacrylate resin such as polymethyl methacrylate (PMMA); a polyolefin resin such as polyethylene (PE) or polypropylene (PP); a polycycloolefin resin; a polyamide resin such as Nylon 6, Nylon 66 or MXD Nylon (m-xylenediamine/adipic acid copolymer); a polyimide resin; a polycarbonate resin; a polyurethane resin; polyvinyl chloride (PVC); triacetyl cellulose (TAC); polylactic acid; a substituted olefin polymer such as polyvinyl acetate or polyvinyl alcohol; a copolymer resin such as EVA, ethylene/vinyl alcohol copolymer, or ethylene/tetrafluoroethylene copolymer; or a combination thereof, of which the polyester resin, polycarbonate resin, EVA, polyvinyl alcohol, Nylon 6, Nylon 66, and ethylene/vinyl alcohol copolymer or the combination thereof are preferred; and polyethylene terephthalate is more preferred. The thickness of the substrate is not particularly limited, and is generally about 15 μm to about 300 μm depending on the requirement of a target product.

The fluoro resin used in the present invention provides the advantage of good weather resistance, and comprises a homopolymer or a copolymer formed from a fluoro olefin monomer selected from the group consisting of monofluoroethylene, vinylidene fluoride, chlorotrifluoroethylene, tetrafluoroethylene, hexafluoropropylene, and a combination thereof, preferably a copolymer formed from a fluoro olefin monomer selected from the group consisting of chlorotrifluoroethylene, tetrafluoroethylene, and a combination thereof, and more preferably a copolymer of chlorotrifluoroethylene.

For example, the fluoro resin used in the present invention may include a copolymer formed with a monomer selected from the group consisting of chlorotrifluoroethylene, tetrafluoroethylene, a vinyl alkyl ether, a vinyl alkanoate and a combination thereof. According to a preferred embodiment of the present invention, the fluoro resin used in the present invention includes a copolymer formed with chlorotrifluoroethylene and a vinyl alkyl ether monomer. When chlorotrifluoroethylene and the vinyl alkyl ether are used as the polymerization units, an alternating copolymer (A-B-A-B) can be easily formed, which is beneficial to the control of the obtained fluoro resin to have a high fluorine content and good physicochemical properties. According to the present invention, the molar ratio of the fluoro olefin monomer to the vinyl alkyl ether monomer is preferably in the range of 3:1 to 1:3 and more preferably in the range of 2:1 to 1:2.

The vinyl alkyl ether monomer used in the present invention is selected from the group consisting of a vinyl linear alkyl ether monomer, a vinyl branched alkyl ether monomer, a vinyl cycloalkyl ether monomer, a vinyl hydroxyalkyl ether monomer, and a combination thereof, and preferably the alkyl in the vinyl alkyl ether is a C₂₋₁₈ alkyl.

The fluoro resin is used in the present invention providing weather resistance, and its content is not particularly limited, and may be any suitable amount well known to persons of ordinary skill in the art. According to the present invention, the amount of the fluoro resin is about 20 wt % to about 95 wt %, preferably about 30 wt % to about 85%, and more preferably about 50 wt % to about 85%, based on the total weight of the solids content of the fluoro-containing coating layer.

Previously, due to the poor adhesion strength between the fluoro resin and the encapsulation material, such as ethylene-vinyl acetate (Ethylene Vinyl Acetate, EVA), the surface of the thin sheet of fluoro resin needs to be modified with as primer, or an adhesion layer is additionally applied to the surface of the thin sheet before the thin sheet is laminated to EVA. The inventors of the present invention finds that addition of a specific adhesion promoter to the fluoro containing coating layer can generate a peeling strength greater than 40 N/cm (about 4 kgf/cm) between the fluoro-containing coating layer of the thin sheet and the encapsulation material of the solar cell module, thereby overcoming the disadvantage of poor adhesion force between the conventional fluoro resin and EVA, and effectively simplifying the process.

The adhesion promoter used in the present invention has the formula below:

R¹Si(R²)₃,

wherein R¹ is an organic group having a terminal amino, isocyanate group, epoxy group, vinyl, or (meth)acryloxy, and R² is each independently selected from the group consisting of a linear or branched C₁₋₄ alkyl, a linear or branched C₁₋₄ alkoxy, and hydroxyl.

R¹ is preferably selected from the group consisting of:

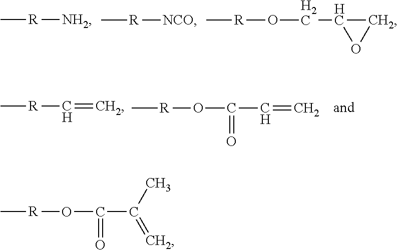

wherein R is a covalent bond, a linear or branched C₁₋₄ alkylene, or a phenylene optionally substituted with 1 to 3 substituents independently selected from a linear or branched C₁₋₄ alkyl.

R² is preferably each independently selected from the group consisting of methoxy, ethoxy, propoxy, methyl, ethyl, and propyl.

Specific examples of the adhesion promoter include, but are not limited to:

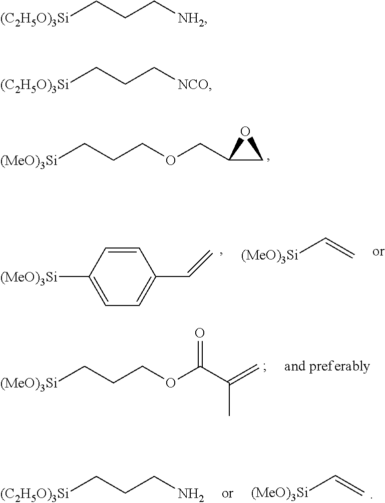

The commercially available adhesion promoter useful in the present invention includes, but is not limited to, substances manufactured by Topco Scientific Co., Ltd. under the trade name KBE-903, KBM-1003, KBM-1403, KBM-403, KBE-9007 or KBM-503.

According to the present invention, the content of the adhesion promoter is about 0.5 wt % to about 15 wt %, and more preferably about 1 wt % to about 9 wt %, based on the trail weight of the solids content of the fluoro-containing coining layer. According to a preferred embodiment of the present invention, if the content of the adhesion promoter is less than 0.5 wt %, the operation can be not easy and the adhesion force cannot be effectively improved; and if the content of the adhesion promoter is higher than 1.5%, the storage stability of the formulated coating could be poor, and the quality and the service life of the fabricated coating layer could be influenced.

As the adhesion promoter used in a too high amount may cause adverse effects to the coating layer, the fluoro-containing coating layer of the present invention further includes an adhesion co-promoter to lower the amount of the adhesion promoter required in the coating layer and maintain a good adhesion force. The addition of both the adhesion promoter and the adhesion co-promoter in the coating layer can create a synergy effect, thereby further improving the adhesion force between the coating layer and the EVA encapsulation material layer.

The content of the adhesion co-promoter is not particularly limited, and may be adjusted according to the content of the adhesion promoter, to achieve the purpose of maintaining an excellent, adhesion force between the coating layer and the EVA encapsulation material layer. According a specific embodiment of the present invention, the content of the adhesion co-promoter is about 1% to about 30%, and preferably about 5% to about 20%, based on the total weight of the solids content of the fluoro-containing coating layer.

The adhesion co-promoter of the present invention is mainly used in combination with the adhesion promoter, to create a synergy effect, so as to further improve the adhesion force between the fluoro-containing coating, layer and the EVA encapsulation material layer. The adhesion co-promoter used in the present invention is well compatible with the fluoro resin, and thus can be directly blended in the fluoro-containing coating, without reacting with the fluoro resin.

In the present invention, a thermoplastic resin is used as the adhesion co-promoter, which is preferably selected from the group consisting of polyurethane resin, ethylene-vinyl acetate resin, polyester resin, an acrylic based resin, and a combination thereof, with the acrylic based resin being more preferred. The thermoplastic resin may be a homopolymer or a copolymer, and may be selected to have a suitable weight average molecular weight (Mw) according to the desired process conditions or properties. Generally, the weight average molecular weight may be less than about 800,000, preferably about 10,000 to about 300,000, and more preferably about 30,000 to about 250,000.

The glass transition temperature (Tg) of the thermoplastic resin needs to fit the processing temperature of EVA, and the thermoplastic resin needs to have a suitable fluidity, so as to facilitate the lamination of the thin sheet to EVA. Moreover, with the increase of the glass transition temperature, the peeling strength between the coating layer and EVA is generally decreased. Therefore, according to a specific embodiment of the present invention, the glass transition temperature of the thermoplastic resin needs to be lower than 150° C., and preferably in the range of 50° C. to 120° C.

Examples of the commercially available polyester resin useful in the present invention include DYNAPOL®L206, DYNAPOL®L205, DYNAPOL®L411, DYNAPOL®LTW, DYNAPOL®LTW-B, and DYNAPOL®LTH (manufactured by Evonik Degussa); VYLON®200, VYLON®270, VYLON®600, VYLON®300, VYLON®500, VYLON®560, VYLON®PCR-925, VYLON®GK100, and VYLON®GK780 (manufactured by TOYOBO Co., Ltd.); SKYBON ES100. SKYBON ES110, SKYBON ES910, SKYBON ES160, SKYBON ES402, SKYBON ES500, and SKYBON ES300 (manufactured by SK Chemicals Co., Ltd.); and ETERKYD 5011-X-50, ETERKYD 5058-R-40, ETERKYD 5021-R-40, ETERKYD 5054-R-40, ETERKYD 5054, ETERKYD 5022-TK-40, ETERKYD 5015-X-50, ETERKYD 5016-X-50, and ETERKYD 5014-X-50 (manufactured by Eternal Chemical Co., Ltd.).

The thermoplastic acrylic based resin of the present invention may be a homopolymer or a copolymer, and preferably a copolymer, which is a polymer derived from at least one monomer selected from acrylic acid, methacrylic acid, an alkyl acrylate, and an alkyl methacrylate.

According to a preferred specific embodiment of the present invention, the selected thermoplastic acrylic based resin has a polymerization unit derived from one or more of the following monomers: acrylic acid, methacrylic acid, methyl acrylate, methyl methacrylate, butyl acrylate, butyl methacrylate, isobutyl acrylate, isobutyl methacrylate, hydroxyethyl acrylate, isobornyl acrylate, isobornyl methacrylate, 2-hydroxyethyl acrylate, 2-hydroxyethyl methacrylate, 2-hydroxypropyl acrylate, and 2-hydroxypropyl methacrylate, of which methyl acrylate, methyl methacrylate, butyl acrylate, butyl methacrylate, isobornyl acrylate, and isobornyl methacrylate are preferred. In addition, the thermoplastic acrylic based resin used by the present invention needs to have a glass transition temperature lower than 150° C., preferably a glass transition temperature ranging from 50° C. to 120° C., and more preferably a glass transition temperature ranging from 60° C. to 110° C.

The thermoplastic acrylic based resin of the present invention ma be any suitable commercially available product, or be prepared by using any method well known to persons of ordinary skill in the art. The preparation method includes, for example, but is not limited to emulsion polymerization, soap/surfactant-free emulsion polymerization, suspension polymerization, dispersion polymerization, or solution polymerization. According to art embodiment of the present invention, the preparation method is suspension polymerization, and the process steps and conditions are well known to persons of ordinary skill in the art.

The examples of the commercially available thermoplastic acrylic based resin useful in the present invention include 7119-TB-50, 7626-1, 7178—TB-50, 7117-TS-50, ETERAC B-761L, ETERAC B-714L, and ETERAC B-7131 (manufactured by Eternal Chemical Co., Ltd.); BR113, BR116, BR-115, BR 106, BR-85, BR-73, MB2952, MB 301.5 and MB 2660 (manufactured by Mitsubishi Chemical Corporation); B-725, B-735, B-736, and B-805 (manufactured by Zeneca Co., Ltd., Netherlands); AR-1042 and AR-1090F (manufactured by Chang Chun Petrochemical Co., Ltd.); A-646, A-14, A-11, A-21, B-60, B-66, B-64, B-82, and B-72 (manufactured by R&H); and FS-2970A (manufactured by Deuchem Co., Ltd.).

The fluoro-containing coating layer of the present invention may include any additive generally known to persons of ordinary skill in the art as desired, which includes, for example, but is not limited to, to colorant, a filler, is curing agent, a curing promoter, a UV absorbent, an anti-static agent, is matting agent, a stabilizer, a cooling aid or an antiflooding agent.

The addition of the colorant in the fluoro-containing coating layer has the effect of improving the aesthetics of the thin sheet, and reflecting the light, thereby improving the light use efficiency. The colorant useful in the present invention can be a pigment, and the type thereof is well known to persons of ordinary skill in the art, which includes, for example, but is not limited to, titanium dioxide, calcium carbonate, carbon black, iron oxide, chrome pigments, and titanium black, with titanium dioxide being preferred. The particle site of the colorant is generally about 0.01 μm to about 20 μm, preferably about 1 μm to about 10 μm.

According to an embodiment of the present invention, the fluoro-containing coating layer may further include a curing agent, which functions to generate an intermolecular chemical bond with the fluoro resin, resulting in crosslinking. The curing agent useful in the present invention is well known to persons of ordinary skill in the art, which includes, for example, but is not limited to, polyisocyanate. Therefore, if present, the amount of the curing agent added is about 1% to about 30%, and preferably about 3% to about 20%, based on the total weight of the solids content of the fluoro-containing coating layer.

The thin sheet of the present invention includes a substrate, and the substrate includes a fluoro-containing coating layer on at least one side. According to an embodiment of the present invention, the substrate has a fluoro-containing coating layer on one side. According to another embodiment of the present invention, the substrate has fluoro-containing coating layers on both sides.

The thin sheet of the present invention may be fabricated by applying the fluoro-containing coating layer to the substrate by using any method known to persons of ordinary skill in the art. For example, a suitable coating may be coated onto the substrate, and then dried to form the fluoro-containing coating layer. The coating method includes, for example, but is not limited to knife coating, roller coating, flexographic coating, thermal transfer coating, micro gravure coating, flow coating, dip coating, spray coating, and curtain coating, or other generally known methods, or as combination thereof.

For example, the thin sheet according to an embodiment of the present invention may be prepared through the following steps:

(a) mixing the fluoro resin, the adhesion promoter, the adhesion co-promoter and an optional additive in a solvent, to form a coating;

(b) coating the coating obtained in Step (a) onto the substrate, and drying it by heating; and

(c) then conducting curing, to form the fluoro-containing coating layer.

The solvent used in Step (a) is not particularly limited, and may be any suitable organic solvent, known to persons of ordinary skilled in the art, which can be, for example, but is not limited to, an alkane, an aromatic hydrocarbon, a ketone, an ester, an ether alcohol or a mixture thereof.

The viscosity of the coating can be adjusted to be in a range suitable for operation by adding the of solvent to the coating. The content of the organic solvent is not particularly limited, and may be adjusted according to practical conditions and requirements, so that the coating has a desired viscosity. According to an embodiment of the present invention, a suitable amount of solvent may be added to control the solids content of the coating in the range of about 10 wt % to about 70 wt % for convenience of operation.

The alkane solvent useful in the present invention includes, for example, but is not limited to, n-hexane, n-heptane, isoheptane or a mixture thereof.

The aromatic hydrocarbon solvent useful the present invention includes, for example, but is not limited to, benzene, toluene, xylene or a mixture thereof.

The ketone solvent useful in the present invention includes, for example, but is not limited to, methyl ethyl ketone (MEK), acetone, methyl isobutyl ketone, cyclohexanone, 4-hydroxy-4-methyl-2-pentanone or a mixture thereof.

The ester solvent useful in the present invention includes, for example but is not limited to, isobutyl acetate (IBAC), ethyl acetate (EAC), butyl acetate (BAC), ethyl formate, methyl acetate, ethoxyethyl acetate, ethoxypropyl acetate, ethyl isobutyrate, propylene glycol monomethyl ether acetate, pentyl acetate or a mixture thereof.

The ether alcohol solvent useful in the present invention includes, for example, but is not limited to, ethylene glycol butyl ether (BCS), ethylene glycol ethyl ether acetate (CAC), ethylene glycol ethyl ether (ECS), propylene glycol methyl ether, propylene glycol methyl ether acetate (PMA), propylene glycol monomethyl ether propionate (PMP), butylene glycol methyl ether (DBE) or a mixture thereof.

The heating temperature and time involved in the above-mentioned Step (b) are not particularly limited, provided that the main purpose of removing the solvent can be achieved. For example, the heating can be conducted at a temperature of 80° C. to 180° C. for 30 sec to 10 min. The curing time in the above-mentioned Step (c) is not particularly limited, and may be, for example, about 1 day to about 3 days.

The thickness of the obtained coating layer is not particularly limited, and the monolayer thickness preferably is in the range of 1 μm to 50 μm, and more preferably is in the range of 5 μm to 30 μm.

The thin sheet of the present invention may be fabricated through the steps of directly applying the coating onto the substrate, and drying and curing the coating. Therefore, compared with the prior art in which the fluoro resin thin sheet needs to be first fabricated and then attached to the substrate, the thin sheet of the present invention has the advantages that the process is convenient and the cost is low.

The present invention further provides a solar cell module having the thin sheet according to the invention. The solar cell module is, for example, but not limited ter, ar crystalline silicon solar cell module or a thin film solar cell module. The solar cell module has a structure well-known to persons of ordinary skill in the art. The crystalline silicon solar cell module may include a transparent front sheet, a back sheet, an encapsulation material layer located between the transparent front sheet and the back sheet, and one or more solar cell units contained in the encapsulation material layer. The thin sheet of the present invention may be directly used as the front sheet or the hack sheet of the solar cell module, and thermal-laminated to the encapsulation material layer.

According to an embodiment of the present intention, the solar cell module of the present invention includes a transparent front sheet, a back sheet, an encapsulation material layer located between the transparent front sheet and the back sheet, and one or more solar cell units contained in the encapsulation material layer, wherein at least one of the transparent front sheet and back sheet includes the thin sheet of the present invention.

Any lamination method well known to persons of ordinary skill in the art can be used to attach the thin sheet of the present invention to the encapsulation material layer. For example, the thin sheet of the present invention can be attached to the encapsulation material layer through vacuum lamination, and the vacuum lamination conditions are not particularly limited. For example, the lamination may be completed by pressurizing for 2 to 20 min at a temperature of 130° C. to 180° C. while a bottom cover of as laminator is adjusted to be at a vacuum level of 20 Pa to 100 Pa and a top cover is adjusted to be under a pressure of 20 kPa to 100 kPa. The pressurization step may be completed in one or more stages.

The thin sheet of the present invention has a good adhesion force with the EVA encapsulation material layer, and thus can be directly laminated to the EVA encapsulation material layer, without the need of a pre-treatment step of coating a primer onto the surface of the thin sheet or corona discharge or using an additional adhesive layer.

The present invention will be further described with reference to the examples below; however the scope of the present invention is not limited thereto. The scope of the present invention is based on what is defined by the claims. It is apparent to persons skilled in the art that various variations, modifications, or replacements may be made to the present invention without departing from the spirit and scope of the present invention.

The abbreviations used herein are defined as follows

EVA: ethylene-vinyl acetate copolymer

PU: polyurethane

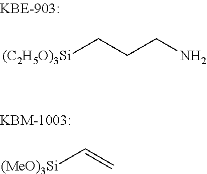

GPC: gel permeation chromatography

DSC: differential scanning calorimetry

The test methods involved in the claimed invention are as follows.

<Test Method of Peeling Strength Between the Thin Sheet and the Eva>:

1. Fabrication of Test Piece:

Two equivalent thin sheets prepared in the examples or comparative examples below are cut into pieces of 15 cm×10.5 cm. The two pieces are overlapped with the long edge (15 cm) in the top-down direction, the short edge (10.5 cm) in the left-right direction, and the coating layers opposite to each other. Then, a tape (MYIGA-19 mm×33 in, manufactured by Symbio Co., Ltd.) of 3.5 cm×10.5 cm is respectively attached to an upper end of the coating layer, and an EVA film (model EV624-EVASKY, manufactured by Bridgestone Corporation) of 13 cm×10.5 cm is sandwiched between the two pieces having the tape, so that the upper ends of the two piece coating layers do not directly contact EVA due to is the presence of the tape, which is convenient for the subsequent peeling strength test.

The fabricated test piece is placed on a laminator (model SML-0808, Chinup Co., Ltd.), and then subjected to a lamination process in which vacuum deaeration (with the top cover pressure being 70 kpa, and a bottom cover pressure being 0 kpa) is conducted for 8 min on a heating plate at a temperature of 50±10° C.; then the top cover is pressurized, with a pressure of 20 kPa for 27 sec in a first stage, a pressure of 40 kPa for 10 sec in a second stage, a pressure of 80 kPa for 6 sec in a third stage, and finally, maintained at the pressure of 80 kPa applied in the third stage for 8 mini and taken out after being cooled to room temperature for EVA peeling strength test.

2. EVA Peeling Strength Test

The test piece after lamination to the EVA film is cut into test strips of 15 cm×1 cm along the long edge, and the portion pre-attached with the tape is torn into two pieces, which are respectively clipped into two jig heads of a micro-computer tensile tester WT-9102, Hung Ta instrument Co., Ltd., having a highest load of 100 kg), but the EVA layer portion is not clipped by the jig heads and is 1 cm away from the two jig heads. The peeling strength test is conducted by oppositely drawing at an angle of 180 degrees in the top to down direction. FIG. 2 is a schematic view of the peeling strength test method, in which 21 is a thin sheet fabricated in the examples or comparative examples, and 22 is the EVA film.

The test is carded out following the ASTM D1876 standard test method. Drawing of the two jig heads is stopped till the distance therebetween is greater than 12 cm, and a corresponding peeling strength value is determined. The drawing rate in the test is 10 cm/min, and the test is passed in case of a peeling strength value of 4 kgf/cm or higher. The results are recorded in Tables 1 to 3.

### PREPARATION EXAMPLES

A. Preparation of Thermoplastic Acrylic Based Resin (B-715H-3, B715H-6, B-715H-9, B-715H-18, and B-715H-25) Through Suspension Polymerization

### Preparation Example A1

An oily phase (100 g methyl methacrylate (Chi Mei Petrochemical Company), 2 g benzoyl peroxide (AKZO Corporation), and 1.2 g thiol (Shanghai Longsheng Chemical Co., Ltd.)) were mixed with an aqueous phase (200 g water and 0.6 g PVA (BP-17 of Chang Chun Petrochemical Co., Ltd.)), dispersed in a reactor with stirring at a rate of 160 rpm, and then heated to 80° C. for polymerization. The reaction was completed after maintenance at 80° C. for 3 hrs. Finally, the solid was washed, dehydrated, and dried, to obtain 95 g of an acrylic based resin as a solid (B-715H-3). The weight average molecular weight measured by GPC (model: Waters 2414 RI) is 30,000; and the Tg measured by DSC (model: TAQ-100) is 118° C.

### Preparation Example A2

Preparation Example A1 was repeated, except that the amount of thiol was 0.5 g, to prepare 95 g of an acrylic based resin as solid (B-715H-6). The weight average molecular weight measured by (PC (model: Waters 2414 RI) is 60,000; and the Tg measured by DSC (model: TAQ-100) is 118° C.

### Preparation Example A3

Preparation Example A1 was repeated, except that the amount of thiol was 0.2 g, to prepare 95 g of an acrylic based resin as solid (B-715H-9). The weight average molecular weight measured by GPC (model: Waters 2414 RI) is 90,000; and the Tg Measured by DSC (model: TAQ-100) is 118° C.

### Preparation Example A4

Preparation Example A1 was repeated, except that no thiol was added, to prepare 95 g of an acrylic based resin as solid (B-715H-18). The weight average molecular weight measured by GPC (model: Waters 2414 RI) is 180,000; and the Tg measured by DSC (model: TAQ-100) is 118° C.

### Preparation Example A5

Preparation Example A1 was repeated, except that no thiol was added and 1.0 g benzoyl peroxide was added instead, to prepare 95 g of an acrylic based resin as solid (B-715H-25). The weight average molecular weight measured by GPC (model: Waters 2414 RI) is 250,000; and the Tg measured by DSC (model: TAQ-100 is 118° C.

B. Preparation of Thermoplastic Acrylic Based Resin (B-715H-18T60 and 8-7158-18T109) Through Suspension Polymerization

### Preparation Example B1

An oily phase (80 g methyl methacrylate (Chi Mei Petrochemical Company), 20 g butyl acrylate (Chi Mei Petrochemical Company), and 2 g benzoyl peroxide (AKZO Corporation)) were mixed with an aqueous phase (200 g pure water and 0.6 g PVA (BP-17 of Chang Chun Petrochemical Co., Ltd.)), dispersed in a reactor with stirring at a rate of 160 rpm, and then heated to 80° C. for polymerization. The reaction was completed after maintenance at 80° C. for 3 hrs. Finally, the solid was washed, dehydrated, and dried, to prepare 95 g of an acrylic based resin as a solid (B-715H-18 T60). The weight average molecular weight measured by GPC (model: Waters 2414 RI) is 180,000; and the Tg measured by DSC (model: TAQ-100) is 60° C.

### Preparation Example B2

Preparation Example B1 was repeated, except that the amounts of methyl methacrylate and butyl acrylate were respectively 955 g and 45 g. to prepare 95 g of an acrylic based resin as solid (B-715H-18 T109). The weight average molecular weight measured by GPC (model: Waters 2414 RI) is 180,000; and the Tg measured by DSC (model: TAQ-100) is 109° C.

C. Preparation a Solutions of PU, EVA, Polyester, and Acrylic Based Resins in Toluene

### Preparation Example C1

90 g toluene was added in a plastic flask, to which 10 g PU resin (solid particles of AH-810L provided by Taiwan Sheen Soon Co., Ltd.) was added with stirring at a high speed and completely dissolved, to prepare a 10% PU-toluene solution.

### Preparation Example C2

The steps of Preparation Example C1 were repeated, except that the PU resin was replaced b an EVA resin (UE-654 solid particles provided by USI Corporation).

### Preparation Example C3

The steps of Preparation Example C1 were repeated, except that the PU resin was replaced by a polyester resin (Eterkyd 5054 solid particles provided by Eternal Chemical Co., Ltd.).

### Preparation Example C4

The steps of Preparation Example C1 were repeated, except that PU resin was replaced by the resin of Preparation Example A4.

### Preparation Example C5

The steps of Preparation Example C1 were repeated, except that the PU resin was replaced by the resin of Preparation Example A1.

### Preparation Example C6

The steps of Preparation Example C1 were repeated, except that the PU resin was replaced by the resin of Preparation Example A2.

### Preparation Example C7

The steps of Preparation Example C1 were repeated, except that the PU resin was replaced by the resin of Preparation Example A3.

### Preparation Example C8

The steps of Preparation Example C1 were repeated, except that the PU resin was replaced by the resin of Preparation Example A5.

### Preparation Example C9

The steps of Preparation Example C were repeated, except that the PU resin was replaced by the resin of Preparation Example B2.

### Preparation Example C10

The steps of Preparation Example C were repeated, except that the PU resin was replaced by the resin of Preparation Example B1.

### COMPARATIVE EXAMPLES A

### Comparative Example A01

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 28 g toluene and 1.9 g of a curing agent (Desmodur 3390 provided by Bayer Corporation, which had a solids content of about 75%, and was an isocyanate curing agent) were sequentially added with stirring at a high speed, to prepare about 43.9 g of a coating having a solids content of about 22.4%.

The coating was coated onto a PET film (CH885 provided by Nanya Corporation, which had a thickness of 250 μm, and was to polyethylene terephthalate film) with an RDS coating rod #50, dried for 1 min at 14° C., and cared for 2 days in an oven at 70° C., to obtain a thin sheet having a thickness of about 20 μm and having a fluoro-containing coating layer. The EVA tensile strength test was conducted, and the peeling strength was measured to be 2.7 kgf/cm on average.

### Comparative Example A02

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to another plastic flask, to which 23.5 g toluene and 9.2 g of the PU-toluene solution of Preparation Example C1 were sequentially added with stirring at a high speed, and finally 1.9 g of a curing agent (Desmodur 3390 provided by Bayer Corporation, which had a solids content of about 75%, and was an isocyanate curing agent) was added, to prepare about 48.6 g of a coating having a solids content of about 22.1%, in which the content of PU was about 8.5 wt %, based on the total weight of the solids Content of the coating.

The coating was coated onto a PET film 85 provided by Nanya Corporation, which had a thickness of 250 μm, and was a polyethylene terephthalate film) with an RDS coating rod #50, dried for 1 min at 140° C., and cured for 2 days in an oven at 70° C., to obtain a thin sheet having a thickness of about 20 μm and having a fluoro-containing coating layer. The EVA tensile strength test was conducted, and the peeling strength was measured to be 1.4 kgf/cm on average.

### Comparative Example A03

14 g of a fluoro resin (Eterflon 4101-60 provided by Eternal Chemical Co., Ltd., which had a solids content of 60%, and was as copolymer resin of chlorotrifluoroethylene and a vinyl alkyl ether) was added to a plastic flask, to which 17.4 g toluene and 21 g of the PU-toluene solution of Preparation Example C1 were sequentially added with stirring at a high speed, and finally 1.9 a of a curing agent (Desmodur 3390 provided by Bayer Corporation, which had a solids content of about 75%, and was an isocyanate curing agent) was added, to prepare about 54.3 p of a coating having a solids content of about 22%, in which the content of PU was about 17.6 wt %, based on the total weight of the solids content of the coating.

The coating was coated onto a PET film (C 885 provided b Nanya Corporation, which had a thickness of 250 μm, and was a polyethylene terephthalate film) with an RDS coating rod #50, dried for 1 min at 140° C., and cured for 2 days in an oven at 70° C., to obtain a thin sheet having a thickness of about 20 μm and having a fluoro-containing coating layer. The EVA tensile strength test was conducted, and the peeling strength was measured to be 0.5 kgf/cm on average.

### Comparative Example A04

The steps of Comparative Example A02 were repeated, except that the PU-toluene solution was replaced by the EVA-toluene solution in Preparation Example C2. The EVA tensile strength test was conducted, and the peeling strength was measured to be 0.3 kgf/cm on average.

### Comparative Example A05

The steps of Comparative Example A03 were repeated, except that the PU-toluene solution was replaced by the EVA-toluene solution in Preparation Example C2. The EVA tensile strength test was conducted, and the peeling strength was measured to be 0.3 kgf/cm on average.

### Comparative Example A06

The steps of Comparative Example A02 were repeated, except that the PU-toluene solution was replaced by the polyester resin-toluene solution in Preparation Example C3. The EVA tensile strength test was conducted, and the peeling strength was measured to be 1.5 kgf/cm on average.

### Comparative Example A07

The steps of Comparative Example A03 were repeated, except that the PU-toluene solution was replaced by the polyester resin-toluene solution in Preparation Example C3. The EVA tensile strength test was conducted, and the peeling strength was measured to be 1.7 kgf/cm on average.

### Comparative Example A08

The steps of Comparative Example A02 were repeated, except that the PU-toluene solution was replaced by the acrylic based resin-toluene solution in Preparation Example C4. The EVA tensile strength test was conducted, and the peeling strength was measured to be 2.0 kgf/cm on average.

### Comparative Example A09

The steps of Comparative Example A03 were repeated, except that the PU-toluene solution was replaced by the acrylic based resin-toluene solution in Preparation Example C4. The EVA tensile strength test was conducted, and the peeling strength was measured a be 2.3 kgf/cm on average.

### EXAMPLES A

### Example A01

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 29.8 g toluene and 0.44 g of an adhesion promoter (KBE-903 provided by Topco Scientific Co., Ltd., which had a Solids content of 100%) were sequentially added with stirring at a high speed, and finally 2.3 g of as curing agent (Desmodur 3390 provided by Bayer Corporation, which had a solids content of about 75%, and was an isocyanate curing agent) was added, to prepare about 46.5 g of a coating having a solids content of about 22.7%, in which the content of the adhesion promoter was about 4.2 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 min at 140° C., and cured for 2 days in an oven at 70° C. to obtain a thin sheet having a thickness of about 20 μm and having a fluoro-containing, coating layer. The EVA tensile strength test was conducted, and the peeling strength was measured to be 7.0 kgf/cm on average.

### Example A02

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 24.9 g toluene, 9.9 g of the resin-toluene solution in Preparation Example C1, and 0.48 g of an adhesion promoter (KBE-903 provided by Topco Scientific Co., Ltd., which had a solids content of 100%) were sequentially added with stirring at a high speed, and finally 2.3 g of as curing agent (Desmodur 3390 provided by Bayer Corporation, which had a solids content of about 75%, and was an isocyanate curing agent) was added, to prepare about 51.6 g of a coating having a solids content of about 22.5%, in which the contents of the polyester resin and the adhesion promoter were respectively about 8.5 wt % and about 4.2 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 min at 140° C., and cured for 2 days in an of at 70° C. to obtain a thin sheet having a thickness of about 20 μm and having a fluoro-containing coating layer. The EVA tensile strength test was conducted, and the peeling strength was measured to be 5.0 kgf/cm on average.

### Example A03

14 g of a fluoro resin (Eterflon 4101-60 provided by Eternal Chemical Co., Ltd., which had a solids content of %, and was a copolymer resin of chlorotrifluoroethylene and as vinyl alkyl ether) was added to a plastic flask, to which 19 g toluene, 22.4 g of the PU resin-toluene solution in Preparation Example C1, and 0.56 g of an adhesion promoter (KBE-903 provided by Topco Scientific Co., Ltd., which had a solids content of 100%) were sequentially added with stirring at a high speed, and finally 2.4 g of a curing agent (Desmodur 3390 provided by Bayer Corporation, which had a solids content of about 75% and was an isocyanate curing agent) was added, to prepare about 58.4 g of a coating having a solids content of about 22.2%, in which the contents of the polyester resin and the adhesion co-promoter were respectively about 17.2 wt % and about 4.2 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 min at 140° C., and cured for 2 days in an oven at 70° C., to obtain as thin sheet having a thickness of about 20 μm and having a fluoro-containing coating layer. The EVA tensile strength test was conducted, and the peeling strength was measured to be 5.1 kgf/cm on average.

### Example A04

The steps of Example A02 were repeated, except that the PU resin-toluene solution was replaced by the EVA resin-toluene solution in Preparation Example C2. The EVA tensile strength test was conducted, and the peeling strength was measured to be 4.8 kgf/cm on average.

### Example A05

The steps of Example A03 were repeated, except that the PU resin-toluene solution was replaced by the EVA resin-toluene solution in Preparation Example C2. The EVA tensile strength test was conducted, and the peeling strength was measured to be 5.6 kgf/cm on average.

### Example A06

The steps of Example A02 were repeated, except that the PU resin-toluene solution was replaced by the polyester resin-toluene solution in Preparation Example C3. The EVA tensile strength test was conducted, and the peeling strength was measured to be 8.1 kgf/cm on average.

### Example A07

The steps of Example A03 were repeated, except that the PU resin-toluene solution was replaced by the polyester resin-toluene solution in Preparation Example C3. The EVA tensile strength test was conducted, and the peeling strength was measured to be 8.3 kgf/cm on average.

### Example A08

The steps of Example A02 were repeated, except that the PU resin-toluene solution was replaced by the acrylic based resin-toluene solution in Preparation Example C4. The EVA tensile strength test was conducted, and the peeling strength was measured to be 8.2 kgf/cm on average.

### Example A09

The steps of Example A03 were repeated, except that the PU resin-toluene solution was replaced by the acrylic based resin-toluene solution in Preparation Example C4. The EVA tensile strength test was conducted, and the peeling strength was measured to be 8.7 kgf/cm on average.

### Example A10

The steps of Example A01 were repeated, except that the adhesion promoter was replaced by KBM-1003 (provided by Topco Scientific Co., Ltd., and having a solids content of 100%). The EVA tensile strength test was conducted, and the peeling strength was measured to be 6.6 kgf/cm on average.

### Example A11

The steps of Example A02 were repeated, except that the adhesion promoter was replaced by KBM-1003 (provided by Topco Scientific Co., Ltd., and having a solids content of 100%). The EVA tensile strength test was conducted, and the peeling strength was measured to be 4.7 kgf/cm on average.

### Example A12

The steps of Example A03 were repeated, except that the adhesion promoter was replaced by KBM-1003 (provided by Topco Scientific Co., Ltd., and having a solids content of 100%). The EVA tensile strength test was conducted, and the peeling strength was measured to be 4.9 kgf/cm on average.

### Example A13

The steps of Example A02 were repeated, except that the PU resin-toluene solution was replaced by the EVA resin-toluene solution in Preparation Example C2, and the adhesion promoter was replaced by KB M-1003 (provided by Topco Scientific Co., Ltd., and having a solids content of 100%). The EVA tensile strength test was conducted, and the peeling strength was measured to be 4.5 kgf/cm on average.

### Example A14

The steps of Example A03 were repeated, except that the PU resin-toluene solution was replaced by the EVA resin-toluene solution in Preparation Example C2 and the adhesion promoter was replaced by KBM-1003 (provided by Topco Scientific Co., Ltd., and having a solids content of 100%). The EVA tensile strength test was conducted, and the peeling strength was measured to 5.3 kgf/cm on average.

### Example A15

The steps of Example A0 were repeated, except that the PU resin-toluene solution was replaced by the polyester resin-toluene solution in Preparation Example C3 and the adhesion promoter was replaced by KBM-1003 (provided by Topco Scientific Co., Ltd., and having a solids content of 100%). The EVA tensile strength test was conducted, and the peeling strength was measured to be 7.3 kgf/cm on average.

### Example A16

The steps of Example A03 were repeated, except that the PU resin-toluene solution was replaced by the polyester resin-toluene solution in Preparation Example C3, and the adhesion promoter was replaced by KBM-1003 (provided by Topco Scientific Co., Ltd., and having a solids content of 100%). The EVA tensile strength test was conducted, and the peeling strength was measured to be 7.6 kgf/cm on average.

### Example A17

The steps of Example A02 were repeated, except that the PU resin-toluene solution was replaced by the acrylic based resin-toluene solution in Preparation Example C4, and the adhesion promoter was replaced by KBM-1003 (provided by Topco Scientific Co., Ltd., and having a solids content of 100%). The EVA tensile strength test was conducted, and the peeling strength was measured to be 7.6 kgf/cm on average.

### Example A18

The steps of Example A03 were repeated, except that the PU resin-toluene solution was replaced by the acrylic based resin-toluene solution in Preparation Example C4 and the adhesion promoter was replaced by KIM-1003 (provided by Topco Scientific Co., Ltd., and having a solids content of 100%). The EVA tensile strength test was conducted, and the peeling strength was measured to be 8.2 kgf/cm on average,

TABLE 1
Influence of the polymer resin added on the peeling strength
between the coating layer and EVA

| | | | | | Peeling |
|---|---|---|---|---|---|
| | Adhesion promoter | | Adhesion co-promoter | | strength |
| | Type | Content | Type | Content | kgf/cm |
| Comparative | — | — | — | — | 2.7 |
| Example A01 | | | | | |
| Comparative | — | — | PU | 8.5 wt % | 1.4 |
| Example A02 | | | | | |
| Comparative | — | — | PU | 17.6 wt % | 0.5 |
| Example A03 | | | | | |
| Comparative | — | — | EVA | 8.5 wt % | 0.3 |
| Example A04 | | | | | |
| Comparative | — | — | EVA | 17.6 wt % | 0.3 |
| Example A05 | | | | | |
| Comparative | — | — | Polyester | 8.5 wt % | 1.5 |
| Example A06 | | | | | |
| Comparative | — | — | Polyester | 17.6 wt % | 1.7 |
| Example A07 | | | | | |
| Comparative | — | — | Acrylic | 8.5 wt % | 2.0 |
| Example A08 | | | based resin | | |
| Comparative | — | — | Acrylic | 17.6 wt % | 2.3 |
| Example A09 | | | based resin | | |
| Example A01 | KBE903 | 4.2 wt % | — | — | 7.0 |
| Example A02 | KBE903 | 4.2 wt % | PU | 8.5 wt % | 5.0 |
| Example A03 | KBE903 | 4.2 wt % | PU | 17.2 wt % | 5.1 |
| Example A04 | KBE903 | 4.2 wt % | EVA | 8.5 wt % | 4.8 |
| Example A05 | KBE903 | 4.2 wt % | EVA | 17.2 wt % | 5.6 |
| Example A06 | DBE903 | 4.2 wt % | Polyester | 8.5 wt % | 8.1 |
| Example A07 | KBE903 | 4.2 wt % | Polyester | 17.2 wt % | 8.3 |
| Example A08 | KBE903 | 4.2 wt % | Acrylic | 8.5 wt % | 8.2 |
| | | | based resin | | |
| Example A09 | KBE903 | 4.2 wt % | Acrylic | 17.2 wt % | 8.7 |
| | | | based resin | | |
| Example A10 | KBM1003 | 4.2 wt % | | | 6.6 |
| Example A11 | KBM1003 | 4.2 wt % | PU | 8.5 wt % | 4.7 |
| Example A12 | KBM1003 | 4.2 wt % | PU | 17.2 wt % | 4.9 |
| Example A13 | KBM1003 | 4.2 wt % | EVA | 8.5 wt % | 4.5 |
| Example A14 | KBM1003 | 4.2 wt % | EVA | 17.2 wt % | 5.3 |
| Example A15 | KBM1003 | 4.2 wt % | Polyester | 8.5 wt % | 7.3 |
| Example A16 | KBM1003 | 4.2 wt % | Polyester | 17.2 wt % | 7.6 |
| Example A17 | KBM1003 | 4.2 wt % | Acrylic | 8.5 wt % | 7.6 |
| | | | based resin | | |
| Example A18 | KBM1003 | 4.2 wt % | Acrylic | 17.2 wt % | 8.2 |
| | | | based resin | | |

It can be seen from the results in Table 1 that:

The coating layer in Comparative Example A01 merely includes fluoro resin and has no any adhesion promoter or adhesion co-promoter added, and the peeling strength between the coating layer and the EVA layer is merely 2.7 kgf/cm, which does not meet the requirement of the tensile strength test standard (>4 kgf/cm) in the industry.

In the coating layers in Comparative Examples A02 to A09, although different polymer resins (the PU, EVA, polyester or acrylic based resin, which is equivalent to the adhesion co-promoter of the present invention) are added, the peeling strength between the fluoro resin coating layer and the EVA layer cannot be improved and is even decreased, in the case that only this type of polymers are added and no adhesion promoter is added.

In the coating layer in Example A01, the adhesion promoter is added, by which the peeling strength is improved to 7.0 kgf/cm, which meets the requirement of the tensile strength test standard (>4 kgf/cm) in the industry.

In Examples A02 to A09, the adhesion promoter of the same content as that in Example A01 is used by which the peeling strength between the fluoro resin coating layer and the EVA layer is improved; and with the addition of as thermoplastic resin such as a polyester resin or a polymethyl methacrylate resin, the peeling strength is further increased. In addition, in Examples A02 to A09, the peeling strength tends to increase with the increase of the amount of the thermoplastic resin added, suggesting that the adhesion promoter and the thermoplastic resin have an obvious synergy effect.

in Examples A10 to A18, the adhesion promoter is further replaced by KBM-1003, and a thermoplastic resin is added, which also have the effect of improving the peeling strength between the fluoro resin coating layer and the EVA layer, and the adhesion promoter and the thermoplastic resin also have a synergy effect.

### EXAMPLES B

### Example B01

The steps of Example A02 were repeated, except that the polyester resin-toluene solution was replaced by the acrylic based resin-toluene solution in Preparation Example C5. The EVA tensile strength test was conducted, and the peeling strength was measured to be 8.0 kgf/cm on average.

### Example B02

The steps of Example A03 were repeated, except that the polyester resin-toluene solution was replaced by the acrylic based resin-toluene solution in Preparation Example C5. The EVA tensile strength test was conducted, and the peeling strength was measured to be 8.1 kgf/cm on average.

### Example B03

The steps of Example A02 were repeated, except that the polyester resin-toluene solution was replaced by the acrylic based resin-toluene solution in Preparation Example C6. The EVA tensile strength test was conducted, and the peeling strength was measured to be 8.5 kgf/cm on average.

### Example B04

The steps of Example A03 were repeated, except that the polyester resin-toluene solution was replaced by the acrylic, based resin-toluene solution in Preparation Example C6. The EVA tensile strength test was conducted, and the peeling strength was measured to be 9.8 kgf/cm on average.

### Example B05

The steps of Example A02 were repeated, except that the polyester resin-toluene solution was replaced by the acrylic based resin-toluene solution in Preparation Example C7. The EVA tensile strength test was conducted, and the peeling strength was measured to be 7.5 kgf/cm on average.

### Example B06

The steps of Example A03 were repeated, except that the polyester resin-toluene solution was replaced by the acrylic based resin-toluene solution in Preparation Example C7. The EVA tensile strength test was conducted, and the peeling strength was measured to be 8.5 kgf/cm on average.

### Example B07

The steps of Example A02 were repeated, except that the polyester resin-toluene solution was replaced by the acrylic based resin-toluene solution in Preparation Example C8. The EVA tensile strength test was conducted, and the peeling strength was measured to be 7.5 kgf/cm on average.

### Example B08

The steps of Example A03 were repeated, except that the polyester resin-toluene solution was replaced by the acrylic based resin-toluene solution in Preparation Example C8. The EVA tensile strength test was conducted, and the peeling strength was measured to be 7.9 kgf/cm on average.

### Example B09

The steps of Example A02 were repeated, except that the polyester resin-toluene solution was replaced by the acrylic based resin-toluene solution in Preparation Example C9. The EVA tensile strength test was conducted, and the peeling, strength was measured to be 8.7 kgf/cm on average.

### Example B10

The steps of Example A02 were repeated, except that the polyester resin-toluene solution was replaced by the acrylic based resin-toluene solution in Preparation Example C10. The EVA tensile strength test was conducted, and the peeling strength was measured to be 8.9 kgf/cm on average.

TABLE 2
Influence of the molecular weight and the glass transition
temperature (Tg) of the acrylic based resin on the peeling strength

| | Acrylic based resin | | | | Peeling |
|---|---|---|---|---|---|
| | | | Molecular | | strength |
| | Model | Tg | weight | Content | kgf/cm |
| Example B01 | B-715H-3 | 118° C. | 30,000 | 8.5 wt % | 8.0 |
| Example B02 | B-715H-3 | 118° C. | 30,000 | 17.2 wt % | 8.1 |
| Example B03 | B-715H-6 | 118° C. | 60,000 | 8.5 wt % | 8.5 |
| Example B04 | B-715H-6 | 118° C. | 60,000 | 17.2 wt % | 9.8 |
| Example B05 | B-715H-9 | 118° C. | 90,000 | 8.5 wt % | 7.5 |
| Example B06 | B-715H-9 | 118° C. | 90,000 | 17.2 wt % | 8.5 |
| Example B07 | B-715H-25 | 118° C. | 250,000 | 8.5 wt % | 7.5 |
| Example B08 | B-715H-25 | 118° C. | 250,000 | 17.2 wt % | 7.9 |
| Example B09 | B-715H-18T109 | 109° C. | 180,000 | 8.5 wt % | 8.7 |
| Example B10 | B-715H-18T60 | 60° C. | 180,000 | 8.5 wt % | 8.9 |
| Example A04 | B-715H-18 | 118° C. | 180,000 | 8.5 wt % | 8.2 |
| Example A05 | B-715H-18 | 118° C. | 180,000 | 17.2 wt % | 8.7 |

It can be seen from Table 2 that:

In Examples B01-B08 and A04-A05, in the case that the content of the adhesion promoter (KBE903) is fixed at 4.2 wt %, and the molecular weight, the glass transition temperature, and the content of the adhesion co-promoter (acrylic based resin) are varied, the resulting peeling strength is higher than 7.0 kgf/cm (that is, higher than the peeling strength obtained in Example A01 in which no adhesion promoter is added). To sum up, the above results suggest that a significant synergy effect can be obtained when the adhesion promoter and the adhesion co-promoter are used in combination.

In Examples B01, B03, B05, B07 and A04, 8.5 wt % of acrylic based resin is used, the glass transition temperature (Tg) is fixed at 110° C., and the molecular weight of the adhesion promoter is changed to be 30,000, 60,000, 90,000, 180,000, or 250,000. The results suggest that the use of the adhesion co-promoters having different molecular weights in this range can exhibit as similar synergy effect. Therefore, an adhesion co-promoter having to suitable molecular weight may be used to prepare the thin sheet of the present invention according to the desired process conditions or properties.

When the content of the acrylic based resin is changed to be 17.2 wt %, the results of Examples B02, B04, B06, B08 and A05 suggest that similar to the result obtained when the content of the acrylic based resin is 8.5 wt %, a synergy effect is exhibit.

Similar to the conclusion obtained in Examples A02-A05 and shown in Table 1, the results of Comparative Examples B01 and B02, B03 and B04, and B05 and B06 also confirm that the peeling strength can be increased with the increase of the content of the adhesion co-promoter.

It can be seen front Examples A04, B09 and B10 according to the present invention that, the synergy effect of the present invention can also be observed in the case that the contents of the adhesion promoter and the adhesion co-promoter ace fixed, and the acrylic based resins having different glass transition temperatures (Tg) (which are 118° C., 109° C. and 60° C. respectively) are used.

### EXAMPLES C

### Example C01

14 g of a fluoro resin (Eterflon 4101-0 provided by Eternal Chemical Co., Ltd., which had a solids content of 60%, and was a copolymer resin of chlorotrifluoroethylene and a vinyl alkyl ether) was added to a plastic flask, 23.7 g toluene, 9.4 g of the acrylic based resin-toluene solution in Preparation Example C4, and 0.1 g of an adhesion promoter (KBE-903 provided by Topco Scientific Co., Ltd., which had a solids content of 100%) were sequentially added with stirring at a high speed, and finally 2.0 g of a curing agent Desmodur 3390 provided by Bayer Corporation, which had a solids content of about 75%, and isocyanate curing agent) was added, to prepare about 49.2 g of a coating having a solids content of about 22.2%, in which the contents of the acrylic based resin and the adhesion promoter were respectively about 8.5 wt % and about 0.9 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 mm at 140° C., and cured for 2 days in an oven at 70° C., to obtain a thin sheet having a thickness of about 20 μm and having a fluoro-containing coating layer. The EVA tensile strength test was conducted, and the peeling strength was measured to be 4.6 kgf/cm on average.

### Example C02

The steps of Example C01 were repeated, except that the amounts of toluene, the acrylic based resin-toluene solution, the adhesion promoter, and the curing agent were respectively 24.0 g, 9.5 g, 0.2 g, and 2.1 g, to prepare about 49.8 g of a coating having a solids content of about 22.3%, in which the contents of the acrylic based resin and the adhesion promoter were respectively about 8.5 wt % and about 1.8 wt %, based on the total weight of the solids content of the coating. The EVA tensile strength test was conducted, and the peeling strength was measured to be 7.2 kgf/cm on average.

### Example C03

The steps of Example C01 were repeated, except that the amounts of toluene, the acrylic based resin-toluene solution, the adhesion promoter, and the curing agent were respectively 24.68 g, 9.96 g, 0.4 g, and 2.26 g, to prepare about 51.3 g of a coating having a solids content of about 22.4%, in which the contents of the acrylic based resin and the adhesion promoter were respectively about 8.5 wt % and about 3.5 wt %, based on the total weight of the solids content of the coating. The EVA tensile strength test was conducted, and the peeling strength was measured to be 7.5 kgf/cm on average.

### Example C04

The steps of Example C01 were repeated, except that the amounts of toluene, the acrylic based resin-toluene solution, the adhesion promoter, and the curing agent were respectively 26 g, 10.2 g, 0.78 g and 2.62 g, to prepare about 53.6 g of a coating having a solids content of about 22.7%, in which the contents of the acrylic based resin and the adhesion promoter were respectively about 8.5 wt % and about 6.4 wt %, based on the total weight of the solids content of the coating. The EVA tensile strength test was conducted, and the peeling strength was measured to be 9.6 kgf/cm on average.

### Example C05

The steps of Example C01 were repeated, except that the amounts of toluene, the acrylic, based resin-toluene solution, the adhesion promoter, and the curing agent were respectively 27.1 g, 10.5 g, 1.1 g and 2.9 g, to prepare about 55.6 g of a coating having, a solids content of about 22.9%, in which the contents of the acrylic based resin and the adhesion promoter were respectively about 8.5 wt % and about 8.5 wt %, based on the total weight of the solids content of the coating. The EVA tensile strength test was conducted, and the peeling strength was measured to be 10.0 kgf/cm on average.

### Example C06

The steps of Example C01 were repeated, except that the amounts of toluene, the acrylic based resin-toluene solution, the adhesion promoter, and the curing agent were respectively 17.8 g, 21.3 g, 0.1 g and 2.0 g, to prepare about 55.2 g of a coating having a solids content of about 22%, in which the contents of the acrylic based resin and the adhesion promoter were respectively about 15.2 wt % and about 0.9 wt %, based on the total weight of the solids content of the coating. The EVA tensile strength test was conducted, and the peeling strength was measured to be 5.4 kgf/cm on average.

### Example C07

The steps of Example C01 were repeated, except that the amounts of toluene, the acrylic based resin-toluene solution, the adhesion promoter, and the curing agent were respectively 18.1 g, 21.5 g, 0.2 g and 2.1 g, to prepare about 55.9 g of a coating having a solids content of about 22%, in which the contents of the acrylic based resin and the adhesion promoter were respectively about 15.2 wt % and about 1.6 wt %, based on the total weight of the solids content of the coating. EVA tensile strength test was conducted, and the peeling strength was measured to be 8.0 kgf/cm on average.

### Example C08

The steps of Example C01 were repeated, except that the amounts of toluene, the acrylic based resin-toluene solution, the adhesion promoter, and the curia agent were respectively 18.7 g, 22.1 g, 0.44 g and 2.32 g, to prepare about 57.6 g of a coating having a solids content of about 22.2%, in which the contents of the acrylic based resin and the adhesion promoter were respectively about 15.2 wt % and about 3.5 wt %, based on the total weight of the solids content of the coating. The EVA tensile strength test was conducted, and the peeling strength was measured to be 8.5 kgf/cm on average.

### Example C09

The steps of Example C01 were repeated, except that the amounts of toluene, the acrylic based resin-toluene solution, the adhesion promoter, and the curing agent were respectively 20 g, 23.6 g, 0.88 g and 2.74 g, to prepare about 61.2 g of a coating having a solids content of about 214%, in which the contents of the acrylic based resin and the adhesion promoter were respectively about 15.2 wt % and about 6.4 wt %, based on the total weight of the solids content of the coating. The EVA tensile strength test was conducted, and the peeling strength was measured to be 10.3 kgf/cm on average.

### Example C1

The steps of Example C01 were repeated, except that the amounts of toluene, the acrylic based resin-toluene solution, the adhesion promoter, and the curing agent were respectively 20.8 g, 24.0 g, 1.2 g and 3.1 g, to prepare about 63.1 g of a coating having a solids content of about 22.7%, in which the contents of the acrylic based resin and the adhesion promoter were respectively about 15.2 wt % and about 8.6 wt %, based on the total weight of the solids content of the coating. The EVA tensile strength test was conducted, and the peeling strength was measured to be 10.5 kgf/cm on average.

TABLE 3
Influence of the contents of the adhesion promoter and
the adhesion co-promoter on the peeling strength

| | Adhesion | Adhesion co-promoter | Peeling |
|---|---|---|---|
| | promoter | (acrylic based resin: | strength |
| | (KBE-903) | B-715H-18) | kgf/cm |
| Example C01 | 0.9 wt % | 8.5 wt % | 4.6 |
| Example C02 | 1.6 wt % | 8.5 wt % | 7.2 |
| Example C03 | 3.5 wt % | 8.5 wt % | 7.5 |
| Example C04 | 6.4 wt % | 8.5 wt % | 9.6 |
| Example C05 | 8.5 wt % | 8.5 wt % | 10.0 |
| Example C06 | 0.9 wt % | 15.2 wt % | 5.4 |
| Example C07 | 1.6 wt % | 15.2 wt % | 8.0 |
| Example C08 | 3.5 wt % | 15.2 wt % | 8.5 |
| Example C09 | 6.4 wt % | 15.2 wt % | 10.3 |
| Example C10 | 8.6 wt % | 15.2 wt % | 10.5 |
| Example A01 | 4.2 wt % | 0 wt % | 7.0 |

It can be seen from the results in Table 3 that:

It can be seen from Examples C01-C10 that the peeling strength between the coating layer of the present invention and EVA can be increased with the increase of the content (0.9-8.6%) of the adhesion promoter.

It can be known from the results of Examples C01 and C06, C02 and C07, C03 and C08, C04 and C09, and C05 and C10 that in the case that the content of the adhesion promoter is fixed, a high peeling strength can be obtained with the increase of the content of the thermoplastic acrylic based resin, and thus the synergy effect is more obvious.

Similar peeling strengths (7.2 kg/cm and 7.0 kg/cm) are obtained in Example C02 and Example A01. The result suggests that use of the adhesion co-promoter can lower the amount of the adhesion promoter.

### Comparative Example D01

7.5 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 14.4 g toluene as a solvent, 22.5 g of the acrylic based resin toluene solution in Preparation Example C4 and 22.5 g titanium dioxide (R-902 provided by DuPont Company) were sequentially added with stirring at a high speed, and finally 5.1 g of a curing agent (Desmodur 3390 provided by Bayer Corporation, which had a solids content of about 75%, and was an isocyanate curing agent) was added, to prepare about 102 g of a coating having a solids content of about 50%, in which the content of titanium dioxide was about 44 wt %, based on the total weight of the solids content of the coating.

The coating was coated onto one side of a polyethylene terephthalate (CH885 provided by Nanya Corporation, which had a thickness of 250 μm, and was a polyethylene terephthalate film) substrate with an RDS coating rod #35, dried for 1 min at 14° C., and cured for 2 days in an oven at 70° C., to obtain a package material having a thickness of about 25 μm and a fluoro-containing coating layer. The EVA tensile strength test was conducted, and the peeling strength was measured to be 1.7 Kg/cm on average.

### Example D01

37.5 g of a fluoro resin (Eterflon 4101-60 provided by Eternal Chemical Co., Ltd., which had a solids content of 50%, and was a copolymer resin of chlorotrifluoroethylene and a vinyl alkyl ether) was added to a plastic flask, to which 18 g toluene as a solvent, 22.5 g of the acrylic based resin-toluene solution in Preparation Example C4, 22.5 g titanium dioxide (R-902 provided by DuPont Company, which had a solids content of 100%), and 3.4 g of an adhesion promoter (KBE-903 provided by Topco Scientific Co., Ltd., which had a solids content of 100%) were sequentially added with stirring at a high speed, and finally 6.9 g of a curing agent (Desmodur 3390 provided by Bayer Corporation, which had a solids content of about 75%, and was an isocyanate curing agent) was added, to prepare about 111 g of a coating having a solids content of about 50%, in which the content of the adhesion promoter was about 6.1 wt %, based on the total weight of the solids content of the coating, and the content of titanium dioxide was about 40 wt %, based on the total weight of the solids content of the coating.

The coating was coated onto one side of a polyethylene terephthalate (CH885 provided by Nanya Corporation, which had a thickness of 250 μm, and was a polyethylene terephthalate film) substrate with an RDS coating rod #35, dried for 1 mm at 140° C., and cured for 2 days in an oven at 70° C., to obtain a package material having a thickness of about 25 μm and a fluoro-containing coating layer. The EVA tensile strength test was conducted, and the peeling strength was measured to be 8.6 Kg/cm on average.

TABLE 4
Influence of addition of the adhesion promoter on the peeling
strength between the thin sheet of the present invention and EVA in
the presence of an additive

| | | Comparative |
|---|---|---|
| | Example D01 | Example D01 |
| Titanium dioxide content | 40 wt % | 44 wt % |
| KBE-903 content | 6 wt % | 0 wt % |
| Peeling strength kgf/cm | 8.6 | 1.7 |

It can be seen from Table 4 that in the presence of the additive (titanium dioxide), use of the adhesion promoter of the present invention can still effectively increase the peeling strength between the fluoro-containing coating layer and the EVA layer.

What is claimed is:

1. A thin sheet for a solar cell module, comprising a substrate and at least one fluoro-containing coating layer, wherein the fluoro containing coating layer comprises:
(a) at fluoro resin, comprising at homopolymer or a copolymer formed with a fluoro olefin monomer selected from the group consisting of monofluoroethylene, vinylidene fluoride, chlorotrifluoroethylene, tetrafluoroethylene, hexafluoropropylene, and at combination thereof;
(b) an adhesion promoter of the formula:
R¹Si(R²)₃,
wherein R¹ is an organic group having a terminal amino, isocyanate group, epoxy group, vinyl or (meth)acryloxy, R² is each independently selected from the group consisting of a linear or branched C₁₋₄ alkyl, a linear or branched C₁₋₄ alkoxy, and hydroxyl; and
(c) an adhesion co-promoter.

2. The thin sheet according to claim 1, wherein the fluoro resin comprises as homopolymer or a copolymer formed with a fluoro olefin monomer selected from the group consisting of chlorotrifluoroethylene, tetrafluoroethylene, and a combination thereof.

3. The thin sheet according to claim 1, wherein the fluoro resin comprises a copolymer formed with chlorotrifluoroethylene and a vinyl alkyl ether monomer.

4. The thin sheet according to claim 3, wherein the vinyl alkyl ether monomer is selected from the group consisting of a vinyl linear alkyl ether monomer, a vinyl branched alkyl ether monomer, a vinyl cycloalkyl ether monomer, a vinyl hydroxyalkyl ether monomer, and a combination thereof.

5. The thin sheet according to claim 1, wherein the fluoro resin is present in an amount of 20% to 95%, based on the total weight of the solids content of the fluoro-containing coating layer.

6. The thin sheet according to claim 1, wherein the adhesion promoter is present in an amount of 0.5 wt % to 15 wt %, based on the total weight of the solids content of the fluoro-containing coating layer.

7. The thin sheet according to claim 1, wherein the substrate comprises a polyester resin, a polyacrylate resin, a polyolefin resin, a polycycloolefin resin, a polyamide resin, a polyimide resin, a polycarbonate resin, a polyurethane resin, a polyvinyl chloride, triacetyl cellulose, polylactic acid or a combination thereof.

8. The thin sheet according to claim 1, wherein R¹ is a group having the structure below: 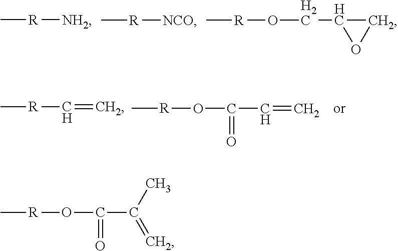
wherein R is a covalent bond, a linear or branched C₁₋₄ alkylene, or a phenylene optionally substituted with 1 to 3 substituents independently selected from a linear or branched C₁₋₄ alkyl.

9. The thin sheet according to claim 1, wherein R² is each independently selected from the group consisting of methoxy, ethoxy, propoxy, methyl, ethyl, and propyl.

10. The thin sheet according to claim 8, wherein the adhesion promoter is:

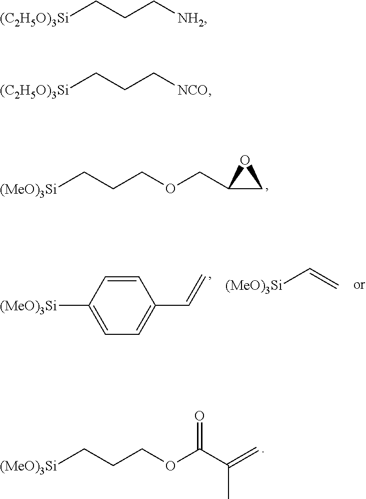

11. The thin sheet according to claim 1, wherein the adhesion co-promoter is a thermoplastic resin.

12. The than shoot according to claim 11, wherein the thermoplastic resin has a glass transition temperature lower than 150° C.

13. The thin sheet according to claim 11, wherein the thermoplastic resin is selected from the group consisting of a polyurethane resin, an ethylene-vinyl acetate resin, an acrylic based resin, a polyester resin and a combination thereof.

14. The thin sheet according to claim 13, wherein the thermoplastic resin is an acrylic based resin.

15. The thin sheet according to claim 1, wherein the adhesion promoter is present in an amount of 1% to 9%, based on the total weight of the solids content of the fluoro-containing coating layer.

16. The thin sheet according to claim 1, wherein the adhesion co-promoter is present in an amount of 5% to 20%, based on the total weight of the solids content of the fluoro-containing coating layer.

17. A solar cell module, comprising the thin sheet according to claim 1.
